(19) United States
(12) Patent Application Publication
(10) Pub. No.: US 2026/0188983 A1
(43) Pub. Date: Jul. 2, 2026

(54) VCSEL ARRAY WITH SUPPRESSED COHERENT COUPLING FROM OPTICAL FEEDBACK

(71) Applicant: TRUMPF PHOTONIC COMPONENTS GMBH, Ulm (DE)

(72) Inventors: Stephan GRONENBORN, Aachen (DE); Sven BADER, Neu-Ulm (DE)

(21) Appl. No.: 19/547,711

(22) Filed: Feb. 24, 2026

Related U.S. Application Data
(63) Continuation of application No. PCT/EP2024/074648, filed on Sep. 4, 2024.

(30) Foreign Application Priority Data
Sep. 7, 2023 (DE) 10 2023 124 160.5

(51) Int. Cl. H01S 5/42; H01S 5/183

(52) U.S. Cl. CPC H01S 5/423; H01S 5/18311

(57) ABSTRACT

A vertical-cavity surface-emitting semiconductor laser (VCSEL) array has two or more VCSELs, where the two or more VCSELs are arranged on a common substrate and each have an epitaxial structure including a laser resonator with a first distributed Bragg reflector (DBR), an active zone, and a second distributed Bragg reflector (DBR). The VCSEL array is designed so that wavelengths of two of the two or more VCSELs differ by at least 0.003 nm and at most 5 nm.

### CROSS REFERENCE TO RELATED APPLICATIONS

This application is a continuation of International Application No. PCT/EP 2024/074648 (WO 2025/051762A1 ), filed on Sep. 4, 2024, and claims benefit to German Patent Application No. DE 10 2023 124 160.5, filed on Sep. 7, 2023. The aforementioned applications are hereby incorporated by reference herein.

### FIELD

The invention relates to an array of vertical-cavity surface-emitting semiconductor lasers (VCSELs) and to a method for producing such a VCSEL array.

### BACKGROUND

In a VCSEL array, a plurality of VCSELs are arranged on a substrate, each VCSEL representing an independent laser source or an independent emitter.

VCSEL arrays are known in principle from U.S. Pat. No. 9,065,254 B2.

VCSELs or VCSEL arrays are used, for example, as radiation sources in sensor technology or in communications engineering, with VCSEL arrays being used in particular in 3D sensor systems and in 3D depth cameras.

VCSELs typically have a semiconductor multilayer structure in which semiconductor layers are epitaxially grown on a substrate in a stacked arrangement. The substrate typically contains a semiconducting material such as gallium arsenide (GaAs) or indium phosphide (InP). A first layer sequence of alternating, thin layers of different refractive indices, which are n-doped, for example, is grown on the substrate to form the first distributed Bragg reflector (DBR). Following the first DBR, the active zone for generating the laser radiation is grown. This can be a so-called quantum well structure. Another layer sequence of alternating, thin layers of different refractive indices, which are p-doped, for example, is grown on the active zone to form the second distributed Bragg reflector or the second DBR.

Together with the active zone located between the two reflectors, the first and the second DBR form the laser resonator. In VCSELs, the laser light is emitted perpendicular to the surface of the VCSEL layers (i.e., in a vertical direction).

The epitaxy described above is merely an example. VCSELs can absolutely have additional (epitaxial) layers. The order of the layers can vary depending on the VCSEL design and desired properties. In particular, VCSELs usually also have an oxide aperture (layer) or a current aperture (layer).

As mentioned above, VCSEL arrays typically have identical VCSELs arranged on the same substrate, for example in a row or as a matrix. In VCSEL arrays produced with good manufacturing homogeneity, the lasers within each array have very similar properties, in particular regarding laser wavelength and polarization.

When two VCSELs are integrated in a module with a slightly reflective interface, such as a protective cover glass, interference effects can occur in the far field. These interference effects can be attributed to spontaneous coherent coupling of the two lasers through optical feedback.

Spontaneous coherent coupling through optical feedback refers to the phenomenon where some of the light emitted from a laser is reflected back into the laser itself and re-enters the active zone. This amount of light that is fed back is called optical feedback.

Optical feedback can be generated in various ways, for example through reflections from external surfaces, in particular cover glass or transparent encapsulations of the VCSELs, or through internal reflections within the laser. This causes the reflected light to interact with the existing light fields in the active zone of the laser.

Optical feedback influences and modulates the emitted light fields in the laser. If the phase relationship between the reflected light and the light already present in the laser is stable, coherent coupling can occur. This means that the reflected light coherently interferes with the existing light waves and is amplified. This causes spatial and temporal modulation of the light fields in the laser.

Spontaneous coherent coupling through optical feedback can have various effects, including the generation of higher orders of modes or the modulation of emission wavelength and intensity. In particular, an inhomogeneous far-field pattern can emerge. Due to the spontaneous, chaotic nature of interference, the positions of minima and maxima are no longer predictable and therefore can also no longer be compensated for. Consequently, desired applications can no longer be controlled as intended. This can lead to mode competition or noise and, in particular, so-called intensity ripples, which can become particularly noticeable in the far field. The intensity ripples arise when the phases of the electric fields of the two or more VCSELs oscillate at exactly the same frequency due to coherent coupling, and the two fields then interfere with each other in the far field. Due to the unknown and fluctuating path length difference between laser 1 (first VCSEL) via the structure that generates the optical feedback (e.g., protective glass) and laser 2 (second VCSEL), the phases can be shifted relative to each other or be the same, but the frequency of the field is aligned. The unknown and chaotic phase shift creates the intensity ripples for different components or different operating conditions for the same component at different positions.

To ensure the desired operating modes and properties of the VCSEL, it is therefore desirable to keep optical feedback as low as possible and to minimize the consequences of the optical feedback.

The optical feedback itself is minimized, for example, by using virtually reflection-free cover glass. Occasionally, however, this phenomenon cannot be completely avoided since, for example, cover glass cannot be made to be as reflection-free as desired.

### SUMMARY

In an embodiment, the present disclosure provides a vertical-cavity surface-emitting semiconductor laser (VCSEL) array has two or more VCSELs, where the two or more VCSELs are arranged on a common substrate and each have an epitaxial structure including a laser resonator with a first distributed Bragg reflector (DBR), an active zone, and a second distributed Bragg reflector (DBR). The VCSEL array is designed so that wavelengths of two of the two or more VCSELs differ by at least 0.003 nm and at most 5 nm.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a schematic sectional view of a VCSEL array according to the prior art;

FIG. 2A, FIG. 2B and FIG. 2C are exemplary illustrations of interference effects due to coherent coupling;

FIG. 3 is a schematic sectional view of a first exemplary embodiment of a VCSEL array according to the present disclosure;

FIG. 4 is a schematic sectional view of a second exemplary embodiment of a VCSEL array according to the present disclosure;

FIG. 5 is a schematic sectional view of a third exemplary embodiment of a VCSEL array according to the present disclosure;

FIG. 6 is a schematic sectional view of a fourth exemplary embodiment of a VCSEL array according to the present disclosure;

FIG. 7 is a schematic top view of another exemplary embodiment of a VCSEL array according to the present disclosure;

FIG. 8 is a schematic top view of another exemplary embodiment of a VCSEL array according to the present disclosure;

FIG. 9 is a schematic top view of another exemplary embodiment of a VCSEL array according to the present disclosure; and

FIG. 10 is a schematic top view of another exemplary embodiment of a VCSEL array according to the present disclosure.

### DETAILED DESCRIPTION

An embodiment of the present disclosure provides an array of vertical-cavity surface-emitting semiconductor lasers (VCSELs), in which the spontaneous coherent coupling of light from the individual VCSELs due to optical feedback is suppressed.

The present disclosure includes a method for producing such a VCSEL array.

A first aspect of the present disclosure includes a VCSEL array comprising two or more VCSELs which are arranged on a common semiconductor substrate. The epitaxial structure of each of the two or more VCSELs comprises a first distributed Bragg mirror/reflector (DBR), an active zone, and a second distributed Bragg mirror/reflector (DBR). A first electrical contact can be provided on each first distributed Bragg reflector and a second electrical contact on each second distributed Bragg reflector.

The first distributed Bragg reflector is preferably grown directly on the substrate. Said DBR consists of a plurality of (dielectric) layers that alternately have a higher or lower refractive index (relative to each other). The maximum reflectivity for a wavelength is achieved when all layers have an optical thickness of exactly one quarter of the wavelength of the particular VCSEL. The first distributed Bragg reflector is preferably n-doped. The second distributed Bragg reflector (which is grown on the active zone or is located on the side of the active zone facing away from the substrate) also has a plurality of (dielectric) layers with alternately higher and lower refractive indices. The same applies to the second distributed Bragg reflector: maximum reflectivity for a wavelength is achieved when all layers have an optical thickness of exactly one quarter of the wavelength of the particular VCSEL. Preferably, the second distributed Bragg reflector is p-doped.

The first electrical contact is attached to, or in contact with, the first distributed Bragg reflector. The first electrical contact is also called the n-contact. The second electrical contact is attached to, or in contact with, the second distributed Bragg reflector. The second electrical contact is also called the p-contact. The n-and the p-contact are used to apply an operating current to the VCSEL.

In at least two of the two or more VCSELs, the wavelengths (of the emitted laser light) differ by at least 0.003 nm and at most 5 nm.

Therefore, the laser wavelengths of the (two) VCSELs of the VCSEL array are deliberately designed to deviate in such a way that the probability of coherent coupling between them through optical feedback is reduced or is no longer possible. To achieve this effect, the two VCSELs must have at least slight differences in their design (in terms of structure and/or material), in their control, and/or in their arrangement on the substrate of the array. In an embodiment of the present disclosure, the two VCSELs preferably have an identical layer structure, as this facilitates production.

Preferably, the difference between the wavelengths of the VCSELs is not too large, so as not to unnecessarily increase the full spectral width of the entire array, for example when a spectral filter is used in the application. The goal is to keep the full spectral width as similar as in a perfectly symmetrical array, but to also have a wavelength difference that is large enough to prevent coherent coupling.

A typical frequency range in which coherent coupling can occur, i.e., the so-called locking range, is from 1 GHz to 10 GHz, which corresponds to a wavelength difference of 0.003 nm to 0.03 nm. The goal is therefore to vary the laser wavelengths of the individual VCSELs or the wavelength difference between the two VCSELs by at least 0.003 nm, in particular by at least 0.01 nm, in particular by at least 0.04 nm, and in particular by at least 0.1 nm.

In other words, the present disclosure provides to deliberately create a difference in wavelength. This approach differs from the usual production procedure, which aims to minimize wavelength variation across the wafer. In contrast, a current typical dispersion of 5 nm over a 4-inch wafer results in a wavelength difference of only 0.005 nm with a VCSEL spacing or pitch of 50 μm and sometimes less, e.g., in the middle of the wafer. For chips with lasers that are often only 30μm to 40μm apart, even the strictest locking criteria of 1 GHz would thus be met if no measures were taken.

An advantage of the given solution is that application-relevant properties such as the (linear) polarization of the VCSELs or the VCSEL array remain unaffected. The overall spectrum width of the VCSEL array is only minimally widened. Another advantage is that it is an on-chip solution, i.e., a solution in which spontaneous coherent coupling is already suppressed by measures on the VCSELs of the VCSEL array on the chip itself. Additional components beyond the VCSEL array (or the chip on which they are mounted) are not necessary.

The aforementioned differences in the wavelengths of the VCSELs in a VCSEL array ensure that a common phase relationship of the light emitted from each of the VCSELs in the array is virtually excluded. Coherent coupling is, however, contingent upon a stable phase relationship. In this respect, even slight wavelength differences in the nanometer or even sub-nanometer range between VCSELs of a VCSEL array are sufficient to suppress coherent coupling of the light from these VCSELs.

Preferably, the VCSEL array is designed in such a way that the wavelengths of the two VCSELs differ by at least 0.003 nm and at most 4 nm, in particular by at least 0.01 nm and at most 2 nm, and in particular by at least 0.04 nm and at most 0.5 nm.

It is also conceivable that the VCSEL array is designed in such a way that the wavelengths of the two VCSELs differ by at least 0.003 nm and at most 0.1 nm or by at least 0.003 nm and at most 0.5 nm. It is also conceivable that the wavelengths of the two VCSELs differ by at least 0.01 nm and at most by 0.1 nm.

In principle, a larger wavelength difference between the two VCSELs tends to prevent spontaneous coherent coupling. However, the wavelength difference should not be chosen to be too large in order to avoid unnecessarily widening the overall spectrum compared to two VCSELs with the same wavelength, for example to allow subsequent narrowband filters to be used, e.g., for signal-to-noise ratio (SNR) improvement, that is, to improve the signal-to-noise ratio.

Preferably, in the VCSEL array, the two VCSELs (with the different wavelengths) are adjacent. The mutual spacing is preferably 20 μm to 50 μm, particularly preferably 30 μm to 40 μm.

In an embodiment of the VCSEL array, the VCSEL array is designed in such a way that the internal temperatures of the two VCSELs differ by at least 0.1 K to 1 K.

The different temperatures of the VCSELs cause the two VCSELs to have slightly different emission wavelengths, even when the semiconductor structure has an identical layer structure. An identical layer structure is particularly advantageous because it can simplify production. Depending on the internal temperature of the VCSEL, firstly, the length of the optical resonator or cavity changes due to expansion effects or contraction effects of the material used, with the result that the wavelength emitted from a VCSEL has a temperature dependence. Secondly, the band structure of the semiconductors used in the VCSEL changes, which also results in a change in wavelength.

Small temperature differences (in the range of a few Kelvin or even below 1 K) between VCSELs or small temperature changes in a VCSEL in such a range do not change the polarization characteristics of the light emitted from the VCSEL(s), or do not change them significantly, meaning that high polarization-extinction ratios can still be achieved. Therefore, the aforementioned temperature difference does suppress spontaneous coherent coupling, but does not (negatively) affect the polarization of the VCSELs of the VCSEL array. One advantage of the proposed solution of the present disclosure is thus that it furthermore allows polarization-selective elements such as polarization filters to be used in a subsequent beam path.

Particularly preferably, the internal temperatures differ by 0.1 K to 0.5 K.

Preferably, the temperature difference between the two VCSELs results from the arrangement of the VCSELs on the substrate.

Preferably, the two VCSELs have the same layer structure and the VCSEL array is designed in such a way that the internal temperature difference between the two VCSELs results from an arrangement of the two VCSELs of the VCSEL array.

In one embodiment, the two VCSELs are designed differently with respect to their heat sinks. A heat sink can be understood to be a structure that dissipates heat for the particular VCSEL.

In one embodiment of the VCSEL array, the two VCSELs are arranged non-symmetrically or asymmetrically on the substrate with respect to the center of the substrate.

As a result, the heat dissipation possibilities for the two VCSELs are typically different, leading to different internal temperatures for the two VCSELs, which in turn allows for different wavelengths of the light emitted from the VCSELs.

In a preferred embodiment, one of the two VCSELs is arranged centrally on the substrate and the other of the two VCSELs is arranged at an edge of the substrate.

The VCSEL at the edge of the substrate therefore has less space for heat dissipation, while the VCSEL placed in the center of the substrate has more space available for heat dissipation. Therefore, this arrangement of the VCSELs results in said two VCSELs differing in their internal temperatures, which in turn causes them to emit different wavelengths.

In another embodiment, the VCSEL array comprises three VCSELs, wherein the distance between one of the two VCSELs (which differ in their wavelengths) and a third VCSEL differs from the distance between another of the two VCSELs and the third VCSEL.

This results in the two VCSELs being given different amounts of space for heat radiation, leading to a difference in internal temperatures.

Furthermore, the third VCSEL can cause an additional heat input and heat the VCSEL located closer to it to a greater extent than the one located further away. This in turn results in a difference in the emitted wavelengths.

According to a further embodiment of the VCSEL array, the two VCSELs furthermore each have an oxide aperture layer with an oxide aperture, wherein the diameters of the oxide apertures of the two VCSELs differ, in particular wherein the diameters of the oxide apertures differ by at least 0.05 μm to 0.5 μm. In particular, the diameters of a mesa of the first VCSEL and of a mesa of the second VCSEL of the two VCSELs can differ, in particular by at least 0.05 to 0.5 μm. The difference in the oxide apertures can be achieved by a corresponding (equally large) difference in the mesa diameters. The different mesa diameters can be achieved by a deliberate variation of the associated masks. With the same (lateral) oxidation depth, different mesa diameters result in different oxide apertures.

This causes the two VCSELs to exhibit different temperature behaviors, which in turn leads to a difference in the emitted wavelengths. One advantage of this embodiment may be that the wavelengths can be adjusted in a simple, well-defined way for one or more individual VCSELs. In particular, a controlled, slight adjustment of the wavelengths is possible.

In a further embodiment of the VCSEL array, the material compositions of the first electrical contact of each of the two VCSELs and/or the second electrical contact of each of the two VCSELs differ. For example, material compositions of layers for contacting, in particular (p-contact) metallization layers of the two VCSELs, differ. In particular, different ohmic resistances are provided.

In other words, for example, the first electrical contact of one of the two VCSELs contains a different material (or material composition) than the other of the two VCSELs. Similarly, the respective second electrical contacts can differ in their materials. Examples of contact materials are titanium (Ti), platinum (Pt), nickel (Ni), gold (Au), and germanium (Ge). Thus, for example, the first electrical contact of one of the two VCSELs can contain titanium, while the first electrical contact of the other of the two VCSELs can contain platinum. This leads to different current conduction (in particular in regard to voltage and current intensity) within the two VCSELs, with the result that the two VCSELs differ in their wavelengths.

In an embodiment of the present disclosure, the surface areas of the first electrical contact of each of the two VCSELs and/or the second electrical contact of each of the two VCSELs differ in size. In one embodiment of the present disclosure, the surface areas of layers, in particular (p-contact) metallization layers, for contacting of the two VCSELs differ in size. Of course, the VCSELs could also be grown in the opposite direction. In this case, for example, n-contact metallization layers can differ in size.

Similarly to different material compositions, a difference in surface area also results in different current conduction or different electrical resistances, thus different power losses and different heating, and ultimately the emission of light of different wavelengths.

Preferably, the surface areas of said electrical contacts differ by at least 5%, more preferably by at least 20%, and even more preferably by at least 50%.

This allows for contact with different ohmic resistances to be provided, resulting in different power losses and different heating, and ultimately the emission of light of different wavelengths.

In another embodiment of the VCSEL array, the two VCSELs are each designed to be supplied with a different operating current.

In another embodiment of the present disclosure, the two VCSELs of the VCSEL array furthermore each have a current aperture layer with a current aperture, wherein the distance between the first electrical contact and the current aperture layer differs in the two VCSELs and/or the distance between the second electrical contact and the current aperture layer differs in the two VCSELs.

This results in different current conduction or different electrical resistances, thus different power losses and different heating, and ultimately the emission of light of different wavelengths.

Preferably, the epitaxial structure of the two VCSELs is identical.

An embodiment of the present disclosure includes a method for producing a VCSEL array.

The method has the same advantages as the VCSEL array according to the present disclosure.

Another aspect of the present disclosure includes a method for operating a VCSEL array comprising two or more VCSELs, wherein the VCSELs are arranged on a common substrate and each have an identical epitaxial structure, wherein two of the VCSELs are supplied with different operating currents.

Further advantages and features can be found in the following description and the appended drawings.

It should be appreciated that the features mentioned above and those to be explained below can be used not only in the combination specified in each case, but also in other combinations or on their own without departing from the scope of the present disclosure.

Exemplary embodiments of the present disclosure are shown in the drawings and are described in more detail below with reference to said drawings.

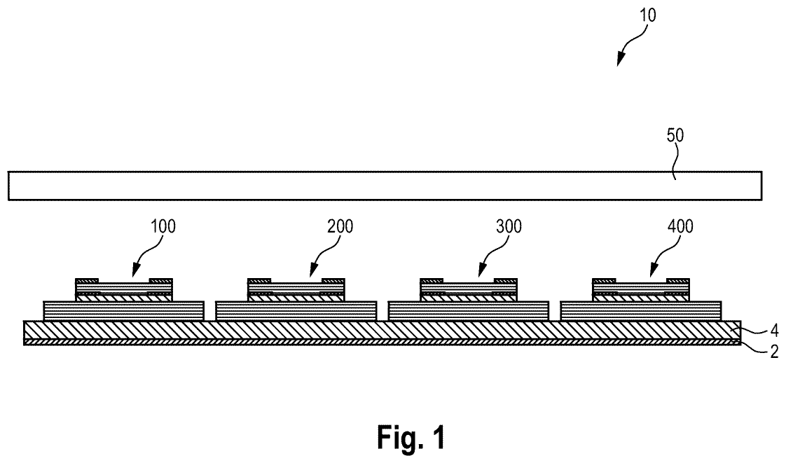

FIGS. 1 and 4 to 6 show various exemplary embodiments of VCSEL arrays. It should be understood that the VCSELs and their structural features shown are not to scale.

FIG. 1 is a schematic sectional view of a VCSEL array 10 according to the prior art. The VCSEL array 10 shown has four VCSELs 100, 200, 300 and 400 which are arranged in a row and share a first electrical contact 2 and a substrate 4. The VCSELs are identical in terms of their structures. The VCSEL array comprises 10 is covered with a highly reflection-free cover glass 50. Since the cover glass 50 is not absolutely reflection-free, optical feedback can occur, which ultimately leads to spontaneous coherent coupling of the light emitted from the individual VCSELs.

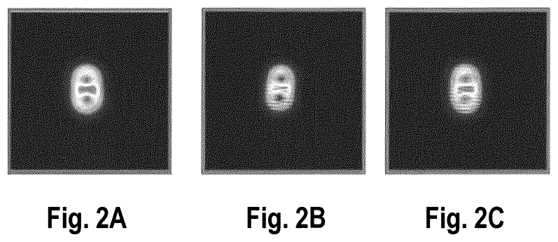

As shown in FIG. 2A to 2C, this may be clearly noticeable in the far field in the form of so-called intensity ripples, as can be seen in particular in FIGS. 2B and 2C. The strip-shaped intensity fluctuations can be clearly seen in FIG. 2B and FIG. 2C.

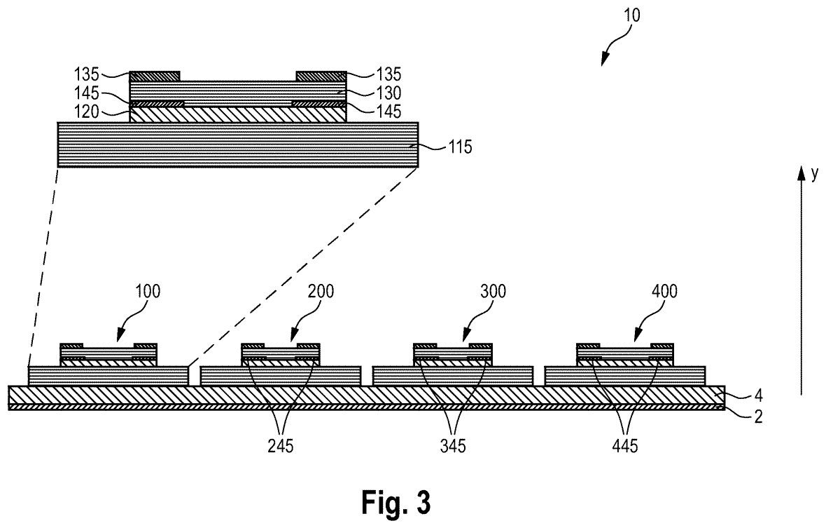

FIG. 3 is a schematic sectional view of a first exemplary embodiment of a VCSEL array 10 with a detailed view of a single VCSEL 100. The VCSEL array 10 shown has four VCSELs 100, 200, 300 and 400 which are arranged in a row (in a dimension perpendicular to the vertical direction y) and share a first electrical contact 2 and a substrate 4. The epitaxial structure of each of the four VCSELs 100, 200, 300 and 400 is grown on the substrate 4. The epitaxial structure of the first VCSEL 100 is shown enlarged. As can be seen from the enlarged view, a first distributed Bragg reflector 115, an active zone 120 and a second distributed Bragg reflector 130 (in this order) have grown or been arranged starting from the substrate 4. Directly above the active zone, i.e., toward the second Bragg reflector, there is an optional current aperture layer 145. A second electrical contact 135 is connected to the second distributed Bragg reflector 130. The first electrical contact 2 is attached to the opposite side of the substrate 4. The first and the second electrical contact are used to apply an operating current to the VCSEL 100.

The (epitaxial) layer structure of the other VCSELs 200, 300, and 400 is identical to that of the VCSEL 100. However, in this exemplary embodiment, the current apertures of the current aperture layers differ. For example, the sizes of the current apertures of the current aperture layers 145 and 445 differ from the current apertures of the current aperture layers 245 and 345. As a result, the VCSELs 100 and 400 provide different distributions of current flow through the VCSELs and thus different ohmic resistances and therefore different power losses, which in turn leads to a difference in the internal temperatures, for example between the two VCSELs 145 and 245. With regard to the wavelengths of the emitted radiation, this (assuming that the same voltage is applied to each of the VCSELs shown) causes the wavelengths of the VCSELs to differ.

Instead of the current aperture layers 145, 245, 345 and 445, oxide aperture layers could also be formed in the respective VCSELs, which layers cause slightly different heating and thus changes in wavelengths.

In an advantageous embodiment, the differences in the current aperture layers or oxide apertures of the respective VCSELs can be produced by differences in the mesa diameters. In this case, oxidation can occur from the side to the same extent or same depth in order to form the oxide apertures. This simplifies the manufacturing process. With the same lateral oxidation, a larger aperture remains in the center with a mesa of larger diameter than with a mesa of smaller diameter.

In the example shown in FIG. 3, the VCSELs 200 and 300 have slightly smaller mesa diameters than the VCSELs 100 and 400. Accordingly, the sizes of the current apertures of the current aperture layers 145 and 445 differ from the current apertures of the current aperture layers 245 and 345. The current apertures of the current apertures 245 and 345 are, according to the smaller mesa diameters, slightly smaller than the current apertures of the current aperture layers 145 and 445.

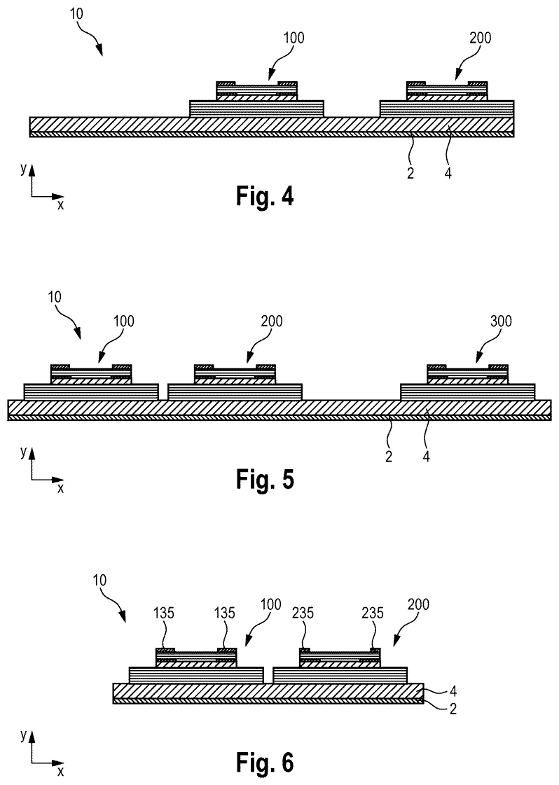

FIG. 4 is a schematic sectional view of a second exemplary embodiment of a VCSEL array 10 comprising two VCSELs 100 and 200. The epitaxy of the VCSELs 100 and 200 is identical. The VCSELs 100 and 200 differ only in respect of their positions on the substrate 4 in the x-direction. While the VCSEL 100 is located substantially in the center of the substrate 4 in the x-direction, the VCSEL 200 is grown at the edge of the substrate 4.

This means that the VCSEL 100 has a larger surface area available for heat dissipation in comparison with the VCSEL 200. The VCSEL 100 therefore heats up less than the VCSEL 200, with the result that the wavelength of the VCSEL 100 differs from that of the VCSEL 200. The arrangement is chosen such that the wavelengths of the VCSELs 100 and 200 differ by at least 0.003 nm and at most 5 nm.

FIG. 5 is a schematic sectional view of a third exemplary embodiment of a VCSEL array 10 comprising three VCSELs 100, 200 and 300. The epitaxy of the VCSELs 100, 200 and 300 is identical. The VCSELs 100 and 200 differ only in respect of their positions on the substrate 4 in the x-direction. The VCSELs 100 and 200 are arranged substantially closer to each other in the x-direction than the VCSELs 200 and 300.

This means that, for example, the VCSEL 300 arranged further away experiences less heat input or, due to the greater distance from other VCSELs as additional heat sources, allows for better heat dissipation than the VCSEL 200 and the VCSEL 100, and thus heats up less, resulting in a difference in wavelength. The arrangement is chosen such that the wavelengths of the VCSELs 100 and 200 differ by at least 0.003 nm and at most 5 nm. The VCSEL array can is designed in such a way that the wavelengths of two of the VCSELs 100, 200, 300 differ by at least 0.003 nm, in particular by at least 0.01 nm, in particular by 0.03 nm, in particular by 0.04 nm, and in particular by 0.1 nm.

FIG. 6 is a schematic sectional view of a fourth exemplary embodiment of a VCSEL array 10 comprising two VCSELs 100 and 200. The epitaxy of the VCSELs 100 and 200 is identical. However, the VCSELs 100 and 200 differ in their designs, in particular in the size of their respective second electrical contacts 135 and 235. The second electrical contact 135 of the first VCSEL 100 has a substantially larger surface area than the second electrical contact 235 of the second VCSEL 200.

As a result, the contact provides a lower electrical resistance, lower thermal power loss, and accordingly heats the VCSEL 100 less, as a result of which the desired slightly different wavelength of the first VCSEL 100 in comparison with the second VCSEL 200 can be achieved. Alternatively or additionally, a contact with a larger surface area can act as a heat sink and enable improved heat dissipation, which is specifically chosen to achieve the desired defined wavelength difference between the two VCSELs.

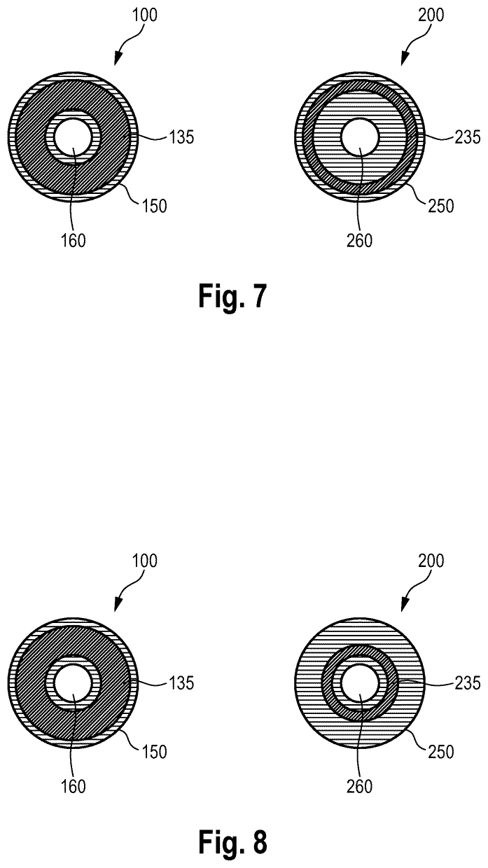

FIGS. 7 to 10 are schematic top views of further exemplary embodiments of a VCSEL array comprising two VCSELs 100 and 200. Each top view schematically shows the second electrical contact 135 of the first VCSEL 100 and the second electrical contact 235 of the second VCSEL 200. Further connecting lines are not shown for the sake of simplicity. The schematic top views also show the mesa 150 and the active area 160 for emitting laser radiation, for example provided by an opening of a current aperture, of the first VCSEL 100, as well as the mesa 250 and the active area 260 of the second VCSEL 200.

In the exemplary embodiment shown in FIG. 7, the second electrical contact 235 of the second VCSEL 200 has a smaller surface area than the second electrical contact 135 of the first VCSEL 100. In other words, the VCSEL array is designed in such a way that the surface areas of layers, in particular metallization layers, for contacting of the two VCSELs differ in size. This is implemented in a similar way in the VCSEL array shown in the schematic sectional view in FIG. 6. Furthermore, the distance from the second electrical contact 235 of the second VCSEL 200 to the active area 260 is greater than the distance from the first electrical contact 135 of the first VCSEL 100 to the active area 160. The greater distance results in a longer path and therefore a slightly higher power loss. This allows a slightly higher temperature of the second VCSEL 200 to be achieved in a targeted manner, but with means that are simple in terms of process engineering, and the VCSEL array being designed with this measure in such a way that the wavelengths of two of the VCSELs differ by at least 0.003 nm and at most 5 nm.

In the exemplary embodiment shown in FIG. 8, the second electrical contact 235 of the second VCSEL 200 has a smaller surface area than the second electrical contact 135 of the first VCSEL 100. This allows the proposed defined wave difference between two VCSELs of the VCSEL array to be achieved. The distance from the second electrical contact 235 of the second VCSEL 200 to the active area 260 and the distance from the first electrical contact 135 of the first VCSEL 100 to the active area 160 can, however, be the same.

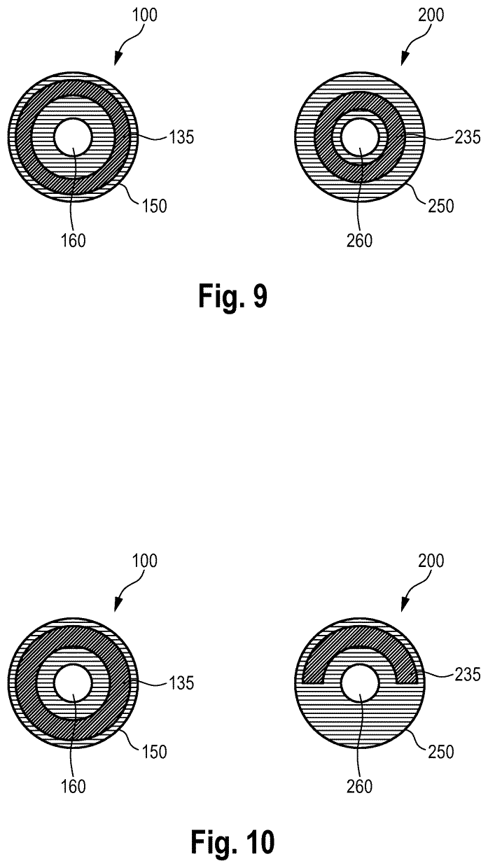

In the exemplary embodiment shown in FIG. 9, the second electrical contact 235 of the second VCSEL 200 and the second electrical contact 135 of the first VCSEL 100 have the same surface area. However, the distance from the second electrical contact 235 of the second VCSEL 200 to the active area 260 is smaller than the distance from the first electrical contact 135 of the first VCSEL 100 to the active area 160. This allows the proposed defined wave difference between two VCSELs of the VCSEL array to be achieved.

In the exemplary embodiment shown in FIG. 10, the second electrical contact 235 of the second VCSEL 200 again has a smaller surface area than the second electrical contact 135 of the first VCSEL 100. In this exemplary embodiment, the second electrical contact 235 is part of the first electrical contact 135. In this case, the second electrical contact 235 is designed, for example, as a semicircle and the first electrical contact 135 as a full circle. This allows the proposed defined wave difference between two VCSELs of the VCSEL array to be achieved.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertical-cavity surface-emitting semiconductor laser (VCSEL) array comprising:
two or more VCSELs, wherein the two or more VCSELs are arranged on a common substrate and each have an epitaxial structure comprising a laser resonator with a first distributed Bragg reflector (DBR), an active zone, and a second distributed Bragg reflector (DBR), and
wherein the VCSEL array is designed so that wavelengths of two of the two or more VCSELs differ by at least 0.003 nm and at most 5 nm.

2. The VCSEL array according to claim 1, wherein the VCSEL array is designed so that the wavelengths of the two VCSELs differ by at least 0.003 nm.

3. The VCSEL array according to claim 1, wherein the VCSEL array is designed so that the wavelengths of the two VCSELs differ by at least 0.003 nm and at most 4 nm.

4. The VCSEL array according to claim 1, wherein the two VCSELs are adjacent.

5. The VCSEL array according to claim 1, wherein the VCSEL array is designed so that internal temperatures of the two VCSELs differ by at least 0.1 K to 1 K.

6. The VCSEL array according to claim 5, wherein the two VCSELs have a same layer structure and the VCSEL array is designed so that an internal temperature difference between the two VCSELs results from an arrangement of the two VCSELs of the VCSEL array.

7. The VCSEL array according to claim 1, wherein the two VCSELs are arranged asymmetrically on the common substrate with respect to a center of the common substrate.

8. The VCSEL array according to claim 1, wherein the VCSEL array has three VCSELs, wherein the distance between one of the two VCSELs and a third VCSEL differs from a distance between another of the two VCSELs and the third VCSEL.

9. The VCSEL array according to claim 1, wherein the two VCSELs each have an oxide aperture layer with an oxide aperture, and wherein diameters of the oxide apertures of the two VCSELs differ.

10. The VCSEL array according to claim 1, wherein material compositions of layers for contacting for contacting of the two VCSELs differ.

11. The VCSEL array according to claim 1, wherein surface areas of layers for contacting of the two VCSELs differ in size.

12. The VCSEL array according to claim 1, wherein the two VCSELs are each designed to be supplied with a different operating current.

13. The VCSEL array according to claim 1, wherein the two VCSELs each have a current aperture, wherein a distance between a metallization layer for contacting and the current aperture differs in the two VCSELs.

14. The VCSEL array according to claim 1, wherein the epitaxial structure of the two VCSELs is identical.

15. A method for producing a vertical-cavity surface-emitting semiconductor laser (VCSEL) array, the method comprising:
arranging two or more VCSELs on a common substrate, wherein the two or more VCSELs each have an epitaxial structure comprising a laser resonator with a first distributed Bragg reflector (DBR), an active zone, and a second distributed Bragg reflector (DBR), and
wherein the VCSEL array is designed so that wavelengths of two of the two or more VCSELs differ by at least 0.003 nm and at most 5 nm.

16. The VCSEL according to claim 1, wherein the VSCEL array is designed so that the wavelengths of the two VSCELs differ by at least 0.01 nm.

17. The VSCEL according to claim 1, wherein the VCSEL array is designed so that the wavelengths of the two VCSELs differ by at least 0.04 nm and at most 0.5 nm.

18. The VSCEL according to claim 1, wherein one of the two VCSELs are arranged centrally on the common substrate and the other of the two VCSELs is arranged at an edge of the common substrate.

19. The VSCEL according to claim 1, wherein the two VCSELs each have an oxide aperture layer with an oxide aperture, and wherein diameters of the oxide apertures of the two VCSELs differ by at least 0.05 μm to 0.5 μm.

20. The VSCEL according to claim 1, wherein material compositions of p contact metallization layers for contacting of the two VCSELs differ, and wherein different ohmic resistances are provided.
